(19) United States
(12) Patent Application Publication
(10) Pub. No.: US 2013/0300400 A1
(43) Pub. Date: Nov. 14, 2013

(54) SYNCHRONOUS RECTIFICATION CIRCUIT AND ASSOCIATED ZERO-CROSSING DETECTION METHOD

(71) Applicant: Chengdu Monolithic Power Systems Co., Ltd., Chengdu (CN)

(72) Inventor: Jiangyun Zhou, Chengu (CN)

(73) Assignee: CHENGDU MONOLITHIC POWER SYSTEMS CO., LTD., Chengdu (CN)

(21) Appl. No.: 13/892,205

(22) Filed: May 10, 2013

(30) Foreign Application Priority Data
May 10, 2012 (CN) 201210144197.7

(51) Int. Cl. G01R 19/00

(52) U.S. Cl. CPC G01R 19/0046
USPC 324/76.71

(57) ABSTRACT

The embodiments of the present invention disclose a synchronous rectification circuit and associated zero-crossing detection method. The synchronous rectification circuit includes a synchronous rectifier having a source, a drain, and at least two gates. The synchronous rectifier having N MOS cells connected in parallel, wherein N is an integer greater than or equal to 2. Through comparing a voltage signal across the drain and the source of the synchronous rectifier with a first and a second threshold voltage, part of the N MOS cells is turned off once the voltage signal is equal to the first threshold voltage, and the left part of the N MOS cells is turned off once the voltage signal is equal to the second threshold voltage. Thus, the accuracy of zero-crossing detection is improved.

### CROSS-REFERENCE TO RELATED APPLICATION(S)

This application claims priority to and the benefit of Chinese Patent Application No. 201210144197.7, filed May 10, 2012, which is incorporated herein by reference in its entirety.

### TECHNICAL FIELD

The present invention generally relates to electronic circuit, and more particularly but not exclusively relates to synchronous rectification circuit and associated zero-crossing detection method.

### BACKGROUND

Synchronous rectification circuit is generally desired to operate in discontinuous current mode (DCM) under light load condition. If the synchronous rectification circuit is allowed to operate in continuous conduction mode (CCM) under light load condition, i.e. when an inductor current I_{L} of the synchronous rectification circuit decreases to zero, a synchronous rectifier of the synchronous rectification circuit is still on, allowing the inductor current I_{L} to continue decreasing, an output capacitor for providing an output voltage can be discharged through the synchronous rectifier. That is to say, if the synchronous rectification circuit is allowed to operate under CCM, the inductor current I_{L} can flow in reverse after crossing zero, and the efficiency of the circuit is greatly reduced.

For solving this problem, the synchronous rectifier is set off when the inductor current I_{L} is deceased to zero to prevent the inductor current from flowing in reverse, i.e. the synchronous rectification circuit operates in DCM. Therefore, a zero-crossing detection circuit is necessary for detecting the zero cross point of the inductor current I_{L} so as to determine whether to turn on or turn off the synchronous rectifier. Usually, inductor current signal is converted to a voltage signal representing the inductor current I_{L} using a conduction resistance R_{L} of the synchronous rectifier, and the voltage signal is provided to a zero-crossing comparator for detecting whether the voltage signal crosses zero. For this method, the accuracy of zero-crossing detection is determined by an input offset voltage V_{OS} of the zero-crossing comparator. Due to the input offset voltage V_{OS} not being zero, the synchronous rectifier can't be turned off accurately at zero of the inductor current I_{L}. In addition, if the conduction resistance R_{L} of the synchronous rectifier is very small, the voltage signal representing the inductor current I_{L} obtained through multiplying the inductor current I_{L} by the conduction resistance R_{L} can be quite small too. When the zero-crossing comparator detects the voltage signal crosses the input offset voltage V_{OS}, the inductor current has actually already decreased far lower than zero. Thus, the accuracy of zero-crossing detection gets worse.

Accordingly, a method and a circuit for improving the accuracy of zero-crossing detection are desired.

### SUMMARY

One embodiment of the present invention discloses a zero-crossing detection method for a synchronous rectification circuit. The synchronous rectification circuit with a synchronous rectifier has a source, a drain, at least two gates; wherein the synchronous rectifier comprises N MOS cells connected in parallel, and N is an integer greater than or equal to 2. the zero-crossing detection method comprises: providing a voltage signal across the drain and the source of the synchronous rectifier indicating a current signal flowing through the drain and the source; comparing the voltage signal with a first threshold voltage signal to determine whether the voltage signal is equal to the first threshold voltage; turning a portion of N MOS cells off once the voltage signal is equal to the first threshold voltage; comparing the voltage signal with a second threshold voltage signal to determine whether the voltage signal is equal to the second threshold voltage; turning the left portion of N MOS cells off once the voltage signal is equal to the second threshold voltage.

Another embodiment of the present invention discloses a synchronous rectification circuit. The synchronous rectification circuit comprises: a switching circuit, at least comprising a power switch and a synchronous rectifier connected in series, wherein the synchronous rectifier has a source, a drain, and at least two gates, and wherein the synchronous rectifier comprises N MOS cells, and N is an integer greater than or equal to 2; a feedback circuit, coupled to the switching circuit and configured to provide a feedback signal; a zero-crossing detection circuit, coupled to a common connection of the power switch and the synchronous rectifier to receive a voltage signal indicating a current flowing through the drain and the source of the synchronous rectifier, and configured to provide a first comparing signal and a second comparing signal based at least in part on the voltage signal; a control circuit, configured to receive the feedback signal and the first and the second comparing signals, and to provide a control signal for the gate of the power switch, and at least two control signals for the at least two gates of the synchronous rectifier.

### BRIEF DESCRIPTION OF THE DRAWINGS

Non-limiting and non-exhaustive embodiments are described with reference to the following drawings. The drawings are only for illustration purpose. Usually, the drawings only show part of the system or circuit of the embodiment, and the same reference label in different drawings have the same, similar or corresponding features or functions.

FIG. 1A illustrates a synchronous rectification circuit according to an embodiment of the present invention.

FIG. 1B illustrates waveforms of signals in the synchronous rectification circuit of FIG. 1A.

FIG. 2 schematically shows a synchronous rectification circuit with a zero-crossing detection circuit according to an embodiment of the present invention.

FIG. 3A schematically shows a synchronous rectifier according to an embodiment of the present invention.

FIG. 3B illustrates a synchronous rectifier according to an embodiment of the present invention.

FIG. 3C illustrates a synchronous rectifier according to an embodiment of the present invention.

FIG. 4 illustrates waveforms of inductor current and drain-source voltage of a synchronous rectifier according to an embodiment of the present invention.

FIG. 5 illustrates a synchronous rectification circuit with a zero-crossing detection circuit according to an embodiment of the present invention.

FIG. 6 illustrates a flow diagram illustrating a zero-crossing detection method of a synchronous rectification circuit according to an embodiment of the present invention.

### DETAILED DESCRIPTION

While the invention will be described in conjunction with the preferred embodiments, it will be understood that they are not intended to limit the invention to these embodiments. On contrary, the embodiments of the present invention is intended to cover alternatives, modifications and equivalents, which may be included within the spirit and scope of the invention as defined by the appended claims. Furthermore, in the following detailed description of the embodiments of the present invention, numerous specific details are set forth in order to provide a thorough understanding of the embodiments of the present invention. However, it will be obvious to one of ordinary skill in the art that without these specific details the present invention may be practiced. In other instance, well-know circuits, materials, and methods have not been described in detail so as not to unnecessarily obscure aspect of the embodiments of the present invention.

The preferred embodiments of the present invention are described with drawings in next.

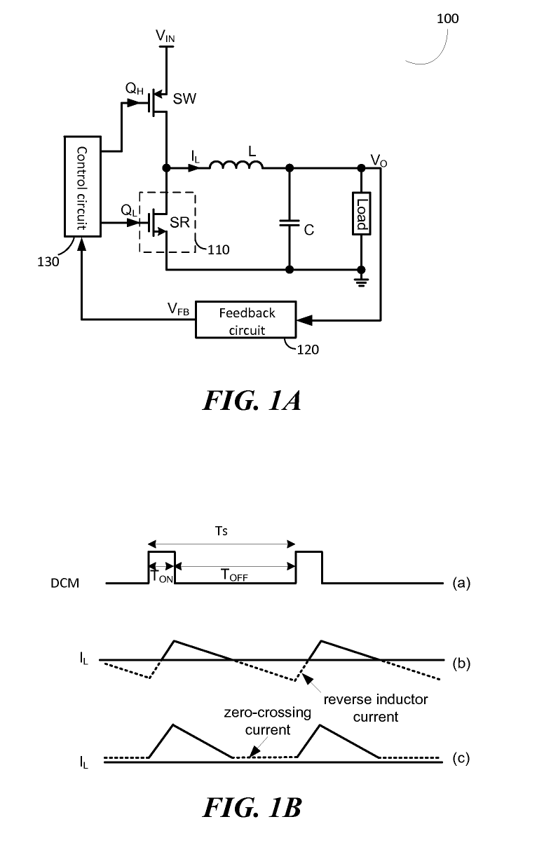

FIG. 1A illustrates a synchronous rectification circuit 100 according to an embodiment of the present invention. The synchronous rectification circuit 100 comprises a power switch SW having a conduction resistance R_{H} between its source and its drain, a synchronous rectifier (SR) 110 having a conduction resistance R_{L} between its source and its drain, an inductor L, a capacitor C and a load. The power switch SW and the synchronous rectifier 110 are connected in series between an input terminal receiving a supply voltage V_{IN} and a reference ground GND. A first terminal of the inductor L is coupled to a common connection of the power switch SW and the synchronous rectifier 110, and a second terminal of the inductor L is coupled to a first terminal of the capacitor C to a first terminal of the load. A second terminal of the capacitor C and a second terminal of the load are connected to the reference ground GND. The synchronous rectification circuit 100 further comprises a feedback circuit 120 and a control circuit 130. The feedback circuit 120 is coupled to an output terminal of the synchronous rectification circuit 100 to receive an output voltage signal V_{O} and provide a feedback signal V_{FB} representing the output voltage signal V_{O}. The control circuit 130 is configured to receive the feedback signal V_{FB} and to provide control signals Q_{H} and Q_{L} respectively to the corresponding gates of the power switch SW and the synchronous rectifier 110. Signals Q_{H} and Q_{L} are used to turn on and turn off the power switch SW and the synchronous rectifier 110 respectively, wherein the signals Q_{H} and Q_{L} are Pulse Width Modulation (PWM) signals.

Synchronous rectification circuit 100 may be a Buck circuit in FIG. 1A, it will be understood that other circuits, e.g. Boost circuit, Fly-back circuit, Forward circuit and Bridge circuit etc. with a synchronous rectifier can be adopted.

FIG. 1B illustrates waveforms of signals in the synchronous rectification circuit 100 in DCM mode. When the control signal Q_{H} is logic high and the control signal Q_{L} is logic low, the power switch SW is set on and the synchronous rectifier 110 is set off so that the inductor L is charged by the supply voltage V_{IN} and the inductor current signal I_{L} is increased. After the inductor current signal I_{L} reaches a peak value, the power switch SW is set off and the synchronous rectifier 110 is set on and thus the inductor current signal I_{L} is decreased. The inductor current signal I_{L} of which waveform is the dotted line as shown in FIG. 1B (b) is reverse after reaching zero if the synchronous rectifier 110 continues in on state. Thus, the efficiency of the circuit 100 is greatly reduced. Usually, the synchronous rectifier 110 is set off when the inductor current I_{L} is deceased to a zero-crossing threshold value (as shown in FIG. 1B (c)). Ideally, the zero-crossing threshold value is zero, but in practice is approximately zero within an acceptable error range.

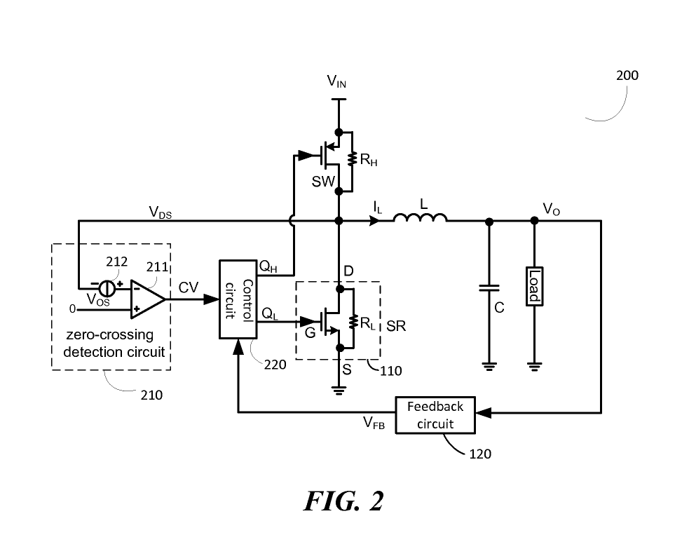

FIG. 2 schematically shows a synchronous rectification circuit 200 with a zero-crossing detection circuit in accordance with an embodiment of the present invention. Compared with the synchronous rectification circuit 100, the synchronous rectification circuit 200 comprises a zero-crossing detection circuit 210 configured to sense the drain-source voltage of the synchronous rectifier 110 and to provide a comparing signal CV. The synchronous rectification circuit 200 further comprises a control circuit 220. The control circuit 220 is configured to receive the comparing signal CV and the feedback signal V_{FB}, and to provide a plurality of control signals Q_{H} and Q_{L} respectively to the power switch SW and the synchronous rectifier 110 for controlling the on and off switching thereof. In the embodiment shown, the synchronous rectifier conduction resistance R_{L} is configured to transform the inductor current signal I_{L} flowing through the source and the drain of the synchronous rectifier 110 to a voltage signal V_{DS} indicating the conduction voltage drop between the source and the drain of the synchronous rectifier 110. The synchronous rectifier 110 is turned on once the power switch SW is turned off, and the inductor current signal I_{L} is freewheeling by the synchronous rectifier 110 so that the voltage signal V_{DS} is negative.

In one embodiment, zero-crossing detection circuit 210 may comprise a zero-crossing comparator 211 having a first input terminal, a second input terminal and an output terminal. Because the input offset voltage signal V_{OS} is a key factor affecting the accuracy of the zero-crossing comparator 211 and unequal to zero, thus the input offset voltage V_{OS} is illustrated as a voltage source 212.

The first input terminal of zero-crossing comparator 211 is coupled to a common connection of the power switch SW and synchronous rectifier 110 to receive the voltage signal V_{DS} with the input offset voltage signal V_{OS} added, and the second input terminal of zero-crossing comparator 211 is configured to receive a reference voltage signal valued zero, and the output terminal of zero-crossing comparator 211 is configured to output a comparing signal CV. The synchronous rectifier 110 will be turned off once the voltage signal V_{DS} is equal to the input offset voltage signal V_{OS}.

In another embodiment, the first input terminal of zero-crossing comparator 211 is configured to receive the voltage signal V_{DS}, the second input terminal of zero-crossing comparator 211 has the input offset voltage signal V_{OS}, and the output terminal of zero-crossing comparator 211 is configured to output the comparing signal CV. The synchronous rectifier 110 will be turned off once the voltage signal V_{DS} is equal to the input offset voltage V_{OS}.

The voltage signal V_{OS}=−R_{L}×I_{L}, if the conduction resistance R_{L} is too small, the voltage signal V_{DS} is also very small which could greatly affects the accuracy of zero-crossing detection. For example, if the input offset voltage signal V_{OS} is 3 mV, and the conduction resistance R_{L} is 3 mΩ, the synchronous rectifier 110 will be turned off when the inductor current reaches 1A which is much larger than the desired value zero.

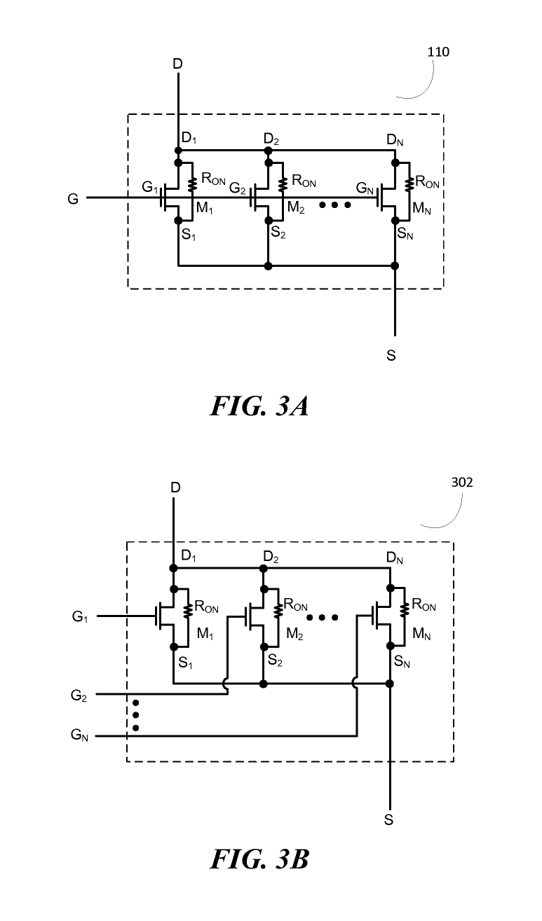

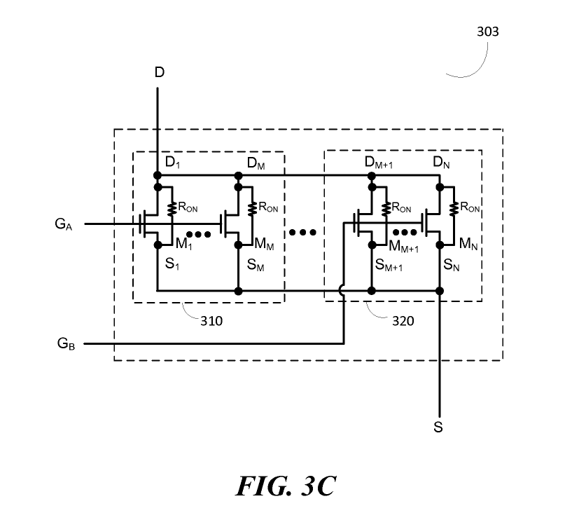

FIG. 3A schematically shows a synchronous rectifier 110 in accordance with an embodiment of the present invention. It's obvious to one of ordinary skill in the art that a MOSFET (i.e. synchronous rectifier) may comprise a large number of MOS cells connected in parallel, the number of which is determined by the size of the MOSFET. As shown in FIG. 3A, the synchronous rectifier 110 may comprise N MOS cells M₁, M₂ . . . M_{N} connected in parallel which are useful to decrease the conduction resistance R_{L} between the drain and the source of the MOSFET, wherein N is an integer greater than or equal to 2 (N≧2). The more MOS cells connected in parallel, the smaller the conduction resistance R_{L}. In the embodiment shown, each MOS cell Mi comprises a source Si, a drain Di, a gate Gi, and a conduction resistance R_{ON}, wherein the conduction resistance R_{ON} is coupled between the drain Di and the source Si of the MOS cells, and wherein the i is a natural number from 1 to N (i=1, 2 . . . N). The drains Di of N MOS cells Mi are connected to each other as a drain D of the synchronous rectifier 110, the sources Si of N MOS cells Mi are connected to each other as a source S of the synchronous rectifier 110, and the gates Gi of N MOS cells Mi are connected to each other as a gate G of the synchronous rectifier 110. The conduction resistance R_{L} of the synchronous rectifier 110 is equal to R_{ON}/N once the gate G of the synchronous rectifier 301 is in active state.

FIG. 3B illustrates a synchronous rectifier 302 according to an embodiment of the present invention. Similar with FIG. 3A, the synchronous rectifier 302 may comprise N MOS cells M₁, M₂ . . . M_{N} paralleled each other, wherein each MOS cell Mi comprises a source Si, a drain Di, and a gate Gi. The drains Di of N MOS cells Mi are connected to each other as a drain D of the synchronous rectifier 302, and the sources Si of N MOS cells Mi are connected to each other as a source S of the synchronous rectifier 302. The gates Gi of the N MOS cells are respectively configured as N gates of the synchronous rectifier. In the embodiment shown in FIG. 3B, the conduction resistance R_{L} of the synchronous rectifier 302 is equal to R_{ON}/N once the N gates of the synchronous rectifier 302 are all in active state.

FIG. 3C illustrates a synchronous rectifier 303 according to another embodiment of the present invention. Similarly, the synchronous rectifier 303 may also comprise N MOS cells M₁, M₂ . . . M_{N} paralleled each other, wherein each MOS cell Mi comprises a source Si, a drain Di, and a gate Gi. The drains Di of MOS cells Mi are connected to each other as a drain D of the synchronous rectifier 303, and the sources Si of MOS cells Mi are connected to each other as a source S of the synchronous rectifier 303. Difference with the synchronous rectifier 302, the N MOS cells of the synchronous rectifier 303 are divided into two parts 310, 320, wherein the part 310 may comprise M MOS cells M₁, M₂ . . . Mₘ, and the part 320 may comprise N-M MOS cells M_{M+1, M}_{M+2} . . . M_{N}, wherein M is a natural number from 1 to N−1 (M=1, 2 . . . N−1). The gates G₁, G₂ . . . G_{M} are connected together as a first gate G_{A} of the synchronous rectifier 303, and the gates G_{M+1}, G_{M+2} . . . G_{N} are connected together as a second gate G_{B} of the synchronous rectifier 303. In the embodiment shown in FIG. 3C, the conduction resistance R_{L} of synchronous rectifier 303 is equal to R_{ON}/N once the two gates G_{A}, G_{B} of the synchronous rectifier 303 are all in active state.

In the embodiments described above, though the N MOS cells of the synchronous rectifier 302 has N gates G₁, G₂ . . . G_{N}, or N MOS cells of the synchronous rectifier 303 are divided into two parts 310, 320 configured to have two gates G_{A}, G_{B}, it should be understood to the one of ordinary skills in the art, the synchronous rectifier 110 may comprise other dividing methods in others embodiments.

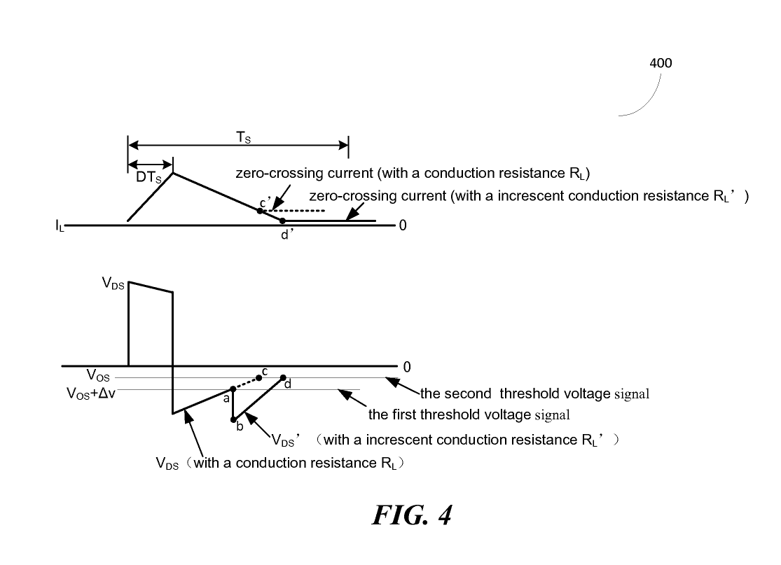

FIG. 4 illustrates waveforms of the inductor current I_{L} and the drain-source voltage V_{DS} of the synchronous rectifier according to an embodiment of the present invention. When the power switch SW is set on, the drain-source voltage V_{DS} of synchronous rectifier is V_{IN}−I_{L}×R_{H}; when the power switch SW is set off and the synchronous rectifier is set on for freewheeling, the absolute value of drain-source voltage V_{DS} is decreased linearly as a result of the inductor current I_{L} decreasing (V_{DS}=−I_{L}×R_{L}). In prior art, when the absolute value of the drain-source voltage V_{DB} with a conduction resistance R_{ON}/N is decreased to the point c as shown in FIG. 4(b), the synchronous rectifier is set off, that is to say, the inductor current I_{L} is decreased to a zero-crossing point c′ which is larger than zero thus the zero-crossing detection is inaccurate.

In order to improve the accuracy of the zero-crossing detection, the conduction resistance R_{L} of the synchronous rectifier may be increased when the drain-source voltage V_{DS} is close to the offset voltage V_{OS}, e.g. V_{OS}+Δv, wherein the value Δv is larger than zero. As shown in FIG. 4, when the absolute value of the drain-source voltage V_{DS} with a conduction resistance R_{ON}/N is decreased to point a as illustrated in FIG. 4(b), the absolute value of the drain-source voltage V_{DS} is raised to point b with an increased conduction resistance R_{L}′ of the synchronous rectifier. The absolute value of the drain-source voltage V_{DS} continues to decrease until reaching point d, where the synchronous rectifier is set off, that is to say, the inductor current I_{L} is decreased to a zero-crossing point d′ which is lower than the zero-crossing point c′ thus the accuracy of zero-crossing detection is improved. For example, the increased conduction resistance R_{L}′ is K times greater than the conduction resistance R_{L}, the value of the inductor current I_{L} at the zero-crossing point d′ is K times lower than the value of the inductor current I_{L} at the zero-crossing point c′, thus the accuracy of zero-crossing detection is increased K times.

Back to the FIG. 3B, when the power switch SW is set off and the synchronous rectifier 302 is set on for freewheeling firstly, the absolute value of drain-source voltage V_{DS} is decreased with a conduction resistance R_{ON}/N as a result of the MOS cells M₁, M₂ . . . M_{N} turning on by the gates G₁, G₂ . . . G₃. After the drain-source voltage V_{DS} is decreased to the point a, the absolute value of drain-source voltage V_{DS} is raised to point b with an increased resistance R_{ON} as a result of M MOS cells turning off, wherein M is determined by the required accuracy. In one embodiment, if the accuracy of zero-crossing detection is needed to increase N times, we can set M to N−1. For example, the MOS cells M₂, M₃ . . . M_{N} are turned off by the gates G₂, G₃ . . . G_{N}, so that the conduction resistance R_{L} is equal to R_{ON} which is N times greater than the original conduction resistance R_{ON}/N and the accuracy of zero-crossing detection is increased N times. Of course, it is also possible to turn other N−1 MOS cells off, e.g. M₁, M₂ . . . M_{N-1} by corresponding gates to increase the conduction resistance R_{L} of the synchronous rectifier 302 N times. In another embodiment, if the accuracy of zero-crossing detection is needed to increase two times, we can set M to N/2, and so on.

And back to FIG. 3C, when the power switch SW is set off and the synchronous rectifier 303 is set on for freewheeling firstly, the absolute value of drain-source voltage V_{DS} is decreased with a conduction resistance R_{ON}/N as a result of the MOS cell parts 310, 320 turning on by the gates G_{A}, G_{B}. After the drain-source voltage V_{DS} is decreased to the point a, the absolute value of drain-source voltage V_{DS} is raised to point b with an increased resistance R_{ON}/M as a result of the MOS cell part 320 turning off by the gate G_{B}. The conduction resistance R_{ON}/N is N/M times greater than the conduction resistance R_{ON}/M, thus the accuracy of zero-crossing detection is increased N/M times, wherein, M is determined by the required accuracy as mentioned in FIG. 3B. In other embodiment, it is also possible to turn the MOS cell part 310 off by corresponding gate to increase the conduction resistance R_{L} of the synchronous rectifier 303.

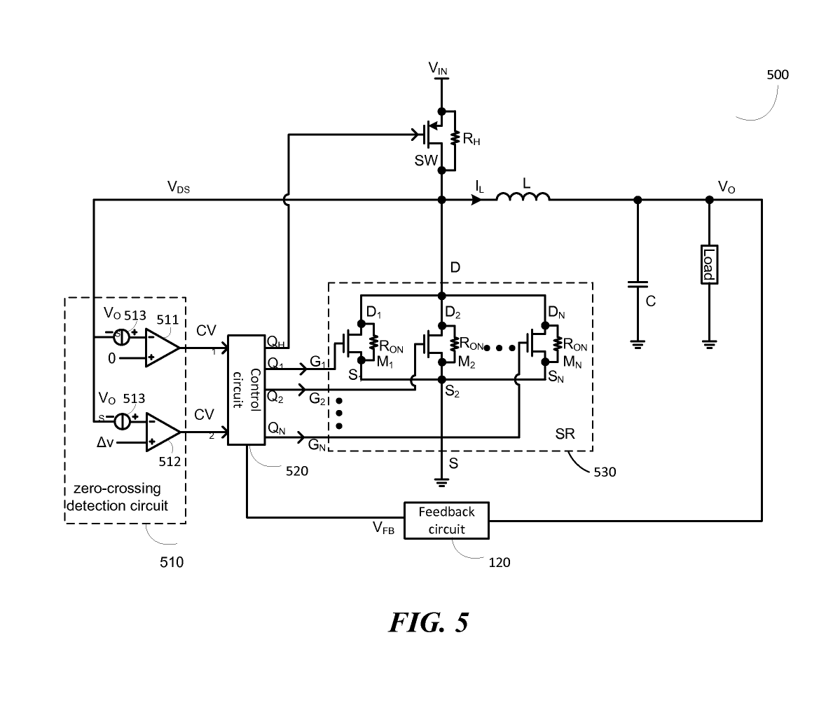

FIG. 5 illustrates a synchronous rectification circuit 500 with a zero-crossing detection circuit according to an embodiment of the present invention. The synchronous rectification circuit 500 may comprises a switching circuit, a feedback circuit 120, a zero-crossing detection circuit 510 and a control circuit 520.

The switching circuit may comprise a power switch SW, a synchronous rectifier 530, an inductor L, a capacitor C and a load. The power switch SW and the synchronous rectifier 530 are connected in series between an input terminal for receiving the supply voltage V_{IN} and the reference ground GND. A first terminal of inductor L is connected to a common connection of the power switch SW and the synchronous rectifier 530, and a second terminal of the inductor L is connected to a first terminal of the capacitor C and to a first terminal of the load. A second terminal of the capacitor C and a second terminal of the load are connected to reference ground GND. The synchronous rectifier 530 is a synchronous rectifier with N gates exported according to an embodiment of the present invention, e.g. the synchronous rectifier 302, the synchronous rectifier 303, and other similar synchronous rectifiers within the spirit and scope of the invention.

The feedback circuit 120 is coupled to an output terminal of the synchronous rectification circuit 500 to receive the output voltage signal V_{O} and provides a feedback signal V_{FB} representing the output voltage signal V_{O}.

The zero-crossing detection circuit 510 further comprises a zero-crossing comparator 511 having a first input terminal, a second input terminal and an output terminal; a zero-crossing comparator 512 having a first input terminal, a second input terminal and an output terminal, Wherein each of the zero-crossing comparator 511 and the zero-crossing comparator 512 has a input offset voltage signal V_{OS} illustrated as a voltage source 513. The input offset voltage signal V_{OS} of the zero-crossing comparator 511 and the input offset voltage signal V_{OS} of the zero-crossing comparator 512 are substantially equal, the difference value between this two input offset voltage signal can be ignored within a certain range.

The first input terminal of zero-crossing comparator 511 is coupled to a common connection of the power switch SW and synchronous rectifier 530 to receive the voltage signal V_{DS} with the input offset voltage signal V_{OS} added, and the second input terminal of zero-crossing comparator 511 receives a reference voltage signal valued zero, and the output terminal of zero-crossing comparator 511 outputs the first comparing signal CV1. The remaining N-MMOS cells of synchronous rectifier 530 will be turned off once the voltage signal V_{DS} is equal to the input offset voltage signal V_{OS}, wherein the input offset voltage signal V_{OS} functions as a first threshold voltage.

The first input terminal of zero-crossing comparator 512 is coupled to a common connection of the power switch SW and synchronous rectifier 530 to receive the voltage signal V_{DS} with the input offset voltage signal V_{OS} added, and the second input terminal of zero-crossing comparator 512 receives a reference voltage signal valued Δv, and the output terminal of zero-crossing comparator 512 outputs the second comparing signal CV2. M MOS cells of the synchronous rectifier 530 will be turned off once the voltage signal V_{DS} is equal to the input offset voltage signal V_{OS} with a voltage signal Δv added, wherein the signal V_{OS} with a voltage signal Δv added functions as a second threshold voltage.

In another embodiment, The first input terminal of zero-crossing comparator 511 is configured to receive the voltage signal V_{DS}, and the second input terminal of zero-crossing comparator 511 having the input offset voltage signal V_{OS}, and the output terminal of zero-crossing comparator 511 is configured to output the first comparing signal CV1. The remaining N-M MOS cells of synchronous rectifier 530 will be turned off once the voltage signal V_{DS} is equal to the input offset voltage signal V_{OS}.

The first input terminal of zero-crossing comparator 512 is coupled to a common connection of the power switch SW and synchronous rectifier 530 to receive the voltage signal V_{DS}, and the second input terminal of zero-crossing comparator 512 is configured to receive the input offset voltage signal V_{OS} with a voltage signal Δv added, and the output terminal of zero-crossing comparator 512 is configured to output the second comparing signal CV2. MMOS cells of the synchronous rectifier 530 will be turned off once the voltage signal V_{DS} is equal to the input offset voltage signal V_{OS} with a voltage signal Δv added.

The control circuit 520 is configured to receive the feedback signal V_{FB}, a first comparing signal CV1 and a second comparing signal CV2, and to provide a control signal Q_{H} to the power switch SW for controlling the on and off switching of the power switch SW. In one embodiment, the control circuit 520 is configured to provide N control signals Q₁, Q₂ . . . Q_{N} respectively to each of the corresponding N gates of the synchronous rectifier 530, to program M of the N control signals to turn the M MOS cells off once the voltage signal is equal to the first threshold voltage; and to program the remaining N-M control signals to turn the remaining N-M MOS cells off once the voltage signal is equal to the second threshold voltage. In another embodiment, the control circuit 520 is configured to provide a first control signal to M gates of the N gates of the rectifier for turning the M MOS cells off once the voltage signal is equal to the first threshold voltage, and to provide a second control signal to the remaining N-M gates of the N gates of the rectifier for turning the remaining N-M MOS cells off once the voltage signal is equal to the second threshold voltage. Wherein the plurality of signals Q_{H}, Q₁, Q₂ . . . Q_{N} are PWM signals.

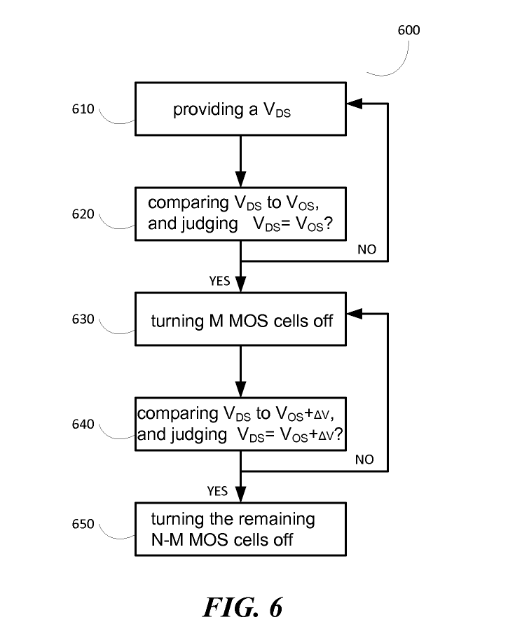

FIG. 6 illustrates a flow diagram illustrating a zero-crossing detection method 600 of a synchronous rectification circuit according to an embodiment of the present invention. The synchronous rectification circuit operated according to the zero-crossing detection method 600 may comprise any one of the synchronous rectification 302, 303, and 530 described above or any variant of the synchronous rectification 302, 303, and 530. The control method 600 may comprise steps 610-640.

In step 610, providing a voltage signal V_{DS} across the drain and the source of the synchronous rectifier indicating an inductor current signal flowing through the drain and the source according to an embodiment of the present invention. The voltage signal V_{DS} may be obtained by sensing a drain-source voltage across the drain and the source of the synchronous rectifier. The synchronous rectifier comprises a conduction resistance between the drain and the source of the synchronous rectifier, wherein providing the voltage signal comprises converting the inductor current signal into the voltage signal V_{DS} by the conduction resistance.

In step 620, comparing the voltage signal V_{DS} with a first threshold voltage signal to determine whether the voltage signal V_{DS} is equal to the first threshold voltage signal. Once the voltage signal V_{DS} is equal to the first threshold voltage, turns to step 630 or else returns to step 610. In this step, a first zero-crossing comparator having a first input terminal, a second input terminal and an output terminal is provided, and wherein the first input terminal receives the voltage signal, the second input terminal receives the first threshold voltage signal.

In step 630, turning M MOS cells of a synchronous rectification off once the voltage signal is equal to the first threshold voltage, wherein the synchronous rectification comprises the synchronous rectification 302, 303, and 530 described above or any variant of them comprise N MOS cells.

In step 640, comparing the voltage signal with a second threshold voltage signal to determine whether the voltage signal is equal to the second threshold voltage. Turns to step 650 once the voltage signal V_{DS} is equal to the first threshold voltage, or returns to step 630. A second zero-crossing comparator having a first input terminal, a second input terminal and an output terminal is needed, and wherein the first input terminal receives the voltage signal, the second input terminal receives a second threshold voltage signal.

In step 650, turning the remaining N-M MOS cells of a synchronous rectification off once the voltage signal is equal to the second threshold voltage.

In the zero-crossing detection method 600 descript above, the first threshold voltage signal is larger than the second threshold voltage signal. And usually, the second threshold voltage signal may comprise an input offset voltage since both the first zero-crossing comparator and the second zero-crossing comparator comprise an input offset voltage signal.

While various embodiments have been described above, it should be understood that they have been presented by way of example only, and not limitation. Thus, the breadth and scope of a present embodiment should not be limited by any of the above-described exemplary embodiments, but should be defined only in accordance with the following claims and their equivalents.

I/We claim:

1. A zero-crossing detection method for a synchronous rectification circuit with a synchronous rectifier having a source, a drain, and a plurality of gates;
wherein the synchronous rectifier comprises N MOS cells connected in parallel, and N is an integer greater than or equal to 2; and
wherein the zero-crossing detection method comprises:
providing a voltage signal across the drain and the source of the synchronous rectifier indicating a current signal flowing through the drain and the source;
comparing the voltage signal with a first threshold voltage signal to determine whether the voltage signal is equal to the first threshold voltage;
turning a portion of N MOS cells off once the voltage signal is equal to the first threshold voltage;
comparing the voltage signal with a second threshold voltage signal to determine whether the voltage signal is equal to the second threshold voltage; and
turning the left portion of N MOS cells off once the voltage signal is equal to the second threshold voltage.

2. The zero-crossing detection method of claim 1, wherein the synchronous rectifier comprises a conduction resistance between the drain and the source of the synchronous rectifier, and wherein providing the voltage signal comprises converting the current signal to the voltage signal by the conduction resistance.

3. The zero-crossing detection method of claim 1, wherein,
each of the N MOS cells has a source, a drain, and a gate; and wherein
the plurality of gates of the synchronous rectifier comprises N gates; and wherein
the sources of the N MOS cells are connected to each other to comprise the source of the synchronous rectifier;
the drains of the N MOS cells are connected to each other to comprise the drain of the synchronous rectifier; and
the N gates of the N MOS cells are respectively configured as the N gates of the synchronous rectifier; and wherein
the zero-crossing detection method further comprises:
providing N control signals respectively to each of the corresponding N gates of the synchronous rectifier;
programming a portion of the N control signals to turn the portion of N MOS cells off once the voltage signal is equal to the first threshold voltage; and
programming the left portion of N control signals to turn the left portion of N MOS cells off once the voltage signal is equal to the second threshold voltage.

4. The zero-crossing detection method of claim 1, wherein,
each of the N MOS cells has a source, a drain, and a gate; and wherein
the plurality of gates of the synchronous rectifier comprises N gates; and wherein
the sources of the N MOS cells are connected to each other to comprise the source of the synchronous rectifier; and
the drains of the N MOS cells are connected to each other to comprise the drain of the synchronous rectifier;
the N gates of the N MOS cells are respectively configured as the N gates of the synchronous rectifier; and wherein
the zero-crossing detection method further comprises:
providing a first control signal to a portion of the N gates of the synchronous rectifier for turning the portion of N MOS cells off once the voltage signal is equal to the first threshold voltage; and
providing a second control signal to the left portion of the N gates of the synchronous rectifier for turning the left portion of N MOS cells off once the voltage signal is equal to the second threshold voltage.

5. The zero-crossing detection method of claim 1, wherein,
each of the N MOS cells has a source, a drain, and a gate; and wherein
the plurality of gates of the synchronous rectifier comprises a first gate and a second gate; and wherein
the sources of the N MOS cells are connected to each other to comprise the source of the synchronous rectifier; and
the drains of the N MOS cells are connected to each other to comprise the drain of the synchronous rectifier;
the gates of a portion of N MOS cells are connected to each other to comprise the first gate; and
the gates of the left portion of N MOS cells are connected to each other to comprise the second gate; and wherein
the zero-crossing detection method further comprises:
providing a first control signal to the first gate to turn a portion of N MOS cells off once the voltage signal is equal to the first threshold voltage; and
providing a second control signal to the second gate to turn the left portion of N MOS cells off once the voltage signal is equal to the second threshold voltage.

6. The zero-crossing detection method of claim 1, wherein, the first threshold voltage signal is larger than the second threshold voltage signal

7. The zero-crossing detection method of claim 1, wherein:
comparing the voltage signal with a first threshold voltage signal to determine whether the voltage signal is equal to the first threshold voltage comprises providing a first zero-crossing comparator having a first input terminal, a second input terminal and an output terminal; wherein the first input terminal is configured to receive the voltage signal, the second input terminal is configured to receive the first threshold voltage signal;
comparing the voltage signal with a second threshold voltage signal to determine whether the voltage signal is equal to the second threshold voltage comprises providing a second zero-crossing comparator having a first input terminal, a second input terminal and an output terminal; wherein the first input terminal is configured to receive the voltage signal, the second input terminal is configured to receive a second threshold voltage signal.

8. The zero-crossing detection method of claim 7, wherein both the first zero-crossing comparator and the second zero-crossing comparator comprise an input offset voltage signal; and wherein the second threshold voltage signal comprises the input offset voltage signal of the second zero-crossing comparator.

9. The zero-crossing detection method of claim 1, wherein, the synchronous rectifier is a MOSFET switch.

10. A synchronous rectification circuit, comprising:
a switching circuit, at least comprising a power switch and a synchronous rectifier connected in series, wherein the synchronous rectifier has a source, a drain, and a plurality of gates, and wherein the synchronous rectifier comprises N MOS cells, and N is an integer greater than or equal to 2;
a feedback circuit, coupled to the switching circuit and configured to provide a feedback signal;
a zero-crossing detection circuit, coupled to a common connection of the power switch and the synchronous rectifier to receive a voltage signal indicating a current flowing through the drain and the source of the synchronous rectifier, and configured to provide a first comparing signal and a second comparing signal based at least in part on the voltage signal;
a control circuit, configured to receive the feedback signal and the first and the second comparing signals, and to provide a control signal for the gate of the power switch, and a plurality of control signals for the plurality of gates of the synchronous rectifier.

11. The zero-crossing detection circuit of claim 10, wherein the synchronous rectifier comprises a conduction resistance between the drain and the source of the synchronous rectifier; and wherein the current flowing through the drain and the source of the synchronous rectifier is converted to the voltage signal by the conduction resistance.

12. The zero-crossing detection circuit of claim 10, wherein each of the N MOS cells has a source, a drain, and a gate; and wherein the plurality of gates of the synchronous rectifier comprises N gates; and wherein
the sources of the N MOS cells are connected to each other to comprise the source of the synchronous rectifier;
the drains of the N MOS cells are connected to each other to comprise the drain of the synchronous rectifier;
the gates of the N MOS cells are respectively configured as the N gates of the synchronous rectifier.

13. The zero-crossing detection circuit of claim 10, wherein each of the N MOS cells has a source, a drain, and a gate; wherein the plurality of gates of the synchronous rectifier comprises a first gate and a second gate; and wherein
the sources of the N MOS cells are connected to each other to comprise the source of the synchronous rectifier;
the drains of the N MOS cells are connected to each other to comprise the drain of the synchronous rectifier;
the gates of a portion of the N MOS cells are connected to each other to comprise the first gate; and
the gates of the left portion of N MOS cells are connected to each other to comprise the second gate.

14. The zero-crossing detection circuit of claim 10, wherein the zero-crossing detection circuit comprises:
a first zero-crossing comparator having a first input terminal, a second input terminal and an output terminal; wherein the first input terminal is configured to receive the voltage signal, the second input terminal is configured to receive a first threshold voltage signal; and wherein a portion of N MOS cells are turn off once the voltage signal is equal to the first threshold voltage signal;
a second zero-crossing comparator having a first input terminal, a second input terminal and an output terminal; wherein the first input terminal is configured to receive the voltage signal, the second input terminal is configured to receive a second threshold voltage signal; and wherein the left portion of N MOS cells are turn off once the voltage signal is equal to the second threshold voltage signal; and wherein
the first threshold voltage signal is larger than the second threshold voltage signal.

15. The zero-crossing detection circuit of claim 14, wherein each of the first zero-crossing comparator and the second zero-crossing comparator comprises an input offset voltage signal; and wherein the second threshold voltage signal comprises the input offset voltage signal of the second zero-crossing comparator.
